(19) United States
(12) Patent Application Publication
(10) Pub. No.: US 2026/0136864 A1
(43) Pub. Date: May 14, 2026

(54) METHOD FOR MANUFACTURING WAFER

(71) Applicant: SK SILTRON CO., LTD., Gumi-si (KR)

(72) Inventor: Jun Won PARK, Gumi-si (KR)

(21) Appl. No.: 19/076,144

(22) Filed: Mar. 11, 2025

(30) Foreign Application Priority Data
Nov. 11, 2024 (KR) 10-2024-0159532

(51) Int. Cl. H01L 21/02

(52) U.S. Cl. CPC H10P 70/56

(57) ABSTRACT

The present invention provides a method for manufacturing a wafer, comprising: a step of rinsing front and backside surfaces of the wafer, a step of securing hydrophobicity of the backside surface of the wafer; a step of improving particles distribution on the backside surface of the wafer, and a step of drying the front and backside surfaces of the wafer.

### CROSS-REFERENCE TO RELATED PATENT APPLICATIONS

This application claims the benefit of Korean Patent Application No. 10-2024-0159532, filed on Nov. 11, 2024, which is hereby incorporated by reference as if fully set forth herein.

### BACKGROUND OF THE INVENTION

### Field of the Invention

The present disclosure relates to a method for manufacturing a wafer, and more specifically, to a method for manufacturing a wafer having a hydrophilic front surface and a hydrophobic backside surface.

### Discussion of the Related Art

A wafer, which is widely used today as a material for manufacturing semiconductor devices, refers to a single-crystal silicon thin plate made using polycrystalline silicon as a raw material.

A silicon wafer may be manufactured through a single crystal growth process for production of an ingot, a slicing process for slicing the ingot, thereby obtaining a wafer having a thin disc shape, an edge grinding process for machining a circumferential portion of the wafer obtained through the slicing process in order to prevent fracture or distortion of the wafer, a lapping process for removing damage, caused by mechanical machining, remaining in the wafer, a polishing process for mirror-polishing the wafer, and a cleaning process for removing an abrasive and foreign matter attached to the polished wafer.

A wafer manufactured in this way is called a polished wafer. On the other hand, an epitaxial wafer is a wafer that has another single crystal film (or “epitaxial layer”) grown on the surface of a polished wafer. It has fewer surface defects than a polished wafer and has the characteristics of being able to control the concentration and type of impurities. The epitaxial layer has high purity and excellent crystal characteristics, which are advantageous in improving the yield and device characteristics of semiconductor devices that are becoming highly integrated.

A halo can occur especially at the edge of the backside surface of an epitaxial wafer. That is, when the front surface and backside surface of the wafer are prepared to be hydrophilic and an epitaxial layer is grown thereafter, the halo can occur at the edge of the backside surface of a hydrophilic wafer.

This halo can be observed with the naked eye, and due to the natural oxide film remaining on the backside surface of the wafer, the epitaxial layer grows abnormally on the backside surface of the wafer, and can be observed as white, especially at the edge.

### SUMMARY OF THE INVENTION

The present invention is intended to solve the above-described problems, and an object of the present invention is to provide a method for manufacturing a polished wafer having a hydrophilic front surface and a hydrophobic backside surface.

The present invention provides a method for manufacturing a wafer, comprising: a step of rinsing the front and backside surfaces of a wafer; a step of securing hydrophobicity of the backside surface of the wafer; a step of improving particles of the backside surface of the wafer; and a step of drying the front and backside surfaces of the wafer.

In the step of securing hydrophobicity of the backside surface of the wafer, the front surface of the wafer may be rinsed and the backside surface of the wafer may be cleaned with hydrofluoric acid.

In the steps of improving particles of the backside surface of the wafer, the front surface of the wafer may be rinsed and the backside surface of the wafer may be cleaned with nitrogen gas.

In the step of drying the front and backside surfaces of the wafer, the wafer may be rotated and dried.

In the step of improving particles of the backside surface of the wafer, the rotation speed of the wafer may be gradually increased from low rpm (Revolutions per minute) to high rpm.

In the step of improving particles of the backside surface of the wafer, nitrogen gas may be supplied at a flow rate of 5 to 15 lpm.

In the step of improving the particles on the backside of the wafer, the rotation speed of the wafer can be started at 150 rpm or less.

In the step of improving the particles on the backside of the wafer, the wafer can be rotated at 150 rpm or less for 2 to 5 seconds.

In the step of improving the particles on the backside of the wafer, the rotation speed of the wafer can be finally set to 1000 rpm or less.

The wafer manufacturing method according to one embodiment of the present invention described above has a hydrophilic front surface and a hydrophobic backside surface, and the particles on the back side are removed, so that the occurrence of a halo at the edge of the back side of the wafer can be prevented in the subsequent epitaxial growth process.

### BRIEF DESCRIPTION OF THE DRAWINGS

The accompanying drawings, which are included to provide a further understanding of the disclosure and are incorporated in and constitute a part of this application, illustrate embodiment(s) of the disclosure and along with the description serve to explain the principle of the disclosure. In the drawings:

FIG. 1. shows one embodiment of a method for manufacturing a wafer according to the present invention;

FIG. 2 shows particle distribution on the backside surface of a wafer after cleaning according to each cleaning condition of Table 1;

FIG. 3 shows particle distribution on the backside surface of a wafer after cleaning according to each cleaning condition of Table 2;

FIG. 4 shows particle distribution on the backside surface of a wafer after cleaning according to each cleaning condition of Table 3;

FIG. 5 shows particle distribution on the backside surface of a wafer when hydrofluoric acid and hydrogen are simultaneously supplied to the wafer and when only hydrofluoric acid is supplied;

FIG. 6 shows particle distribution on the backside surface of a wafer after cleaning according to each case of Table 2;

FIG. 7 shows particle distribution on the backside surface of a wafer after cleaning according to the supply flow rate of nitrogen gas.

### DETAILED DESCRIPTION OF THE INVENTION

Hereinafter, the present disclosure will be described with reference to embodiments, for concrete description thereof, and the embodiments will be described in detail with reference to the accompanying drawings, for better understanding of the present disclosure.

However, the embodiments of the present disclosure may be modified to various different forms, and the scope of the present disclosure should not be interpreted as being limited to embodiments described below. The embodiments of the present disclosure are provided to more fully describe the present disclosure to those having ordinary skill in the art.

In addition, although relational terms such as “first”, “second”, “upper”, “lower”, etc. may be construed only to distinguish one element from another element without necessarily requiring or involving a certain physical or logical relation or sequence between the elements.

FIG. 1 is a drawing showing an embodiment of a method for manufacturing a wafer according to the present invention.

The method for manufacturing a wafer according to the present embodiment includes a step of rinsing the front and backside surfaces of the wafer S110, a step of securing hydrophobicity of the backside surface of the wafer S120, a step of improving particles on the backside surface of the wafer S130, and a step of drying the front and backside surfaces of the wafer S140. Here, steps S110 to S130 may all be steps of cleaning the front and backside surfaces of the wafer.

First, a polished wafer that has undergone single crystal growth, slicing, edge grinding, lapping, and polishing is prepared.

Then, the front and backside surfaces of the wafer are rinsed to remove foreign substances including impurities on the surface. This rinsing process can be performed by injecting the wafer into a cleaning tank to rinse the front and backside surfaces of the wafer together S110. The rinsing process can be performed using, for example, deionized water.

At this time, the flow rates of the supplied hydrofluoric acid and deionized water may be the same, and since the hydrofluoric acid and deionized water are supplied while rotating the wafer, most of the hydrofluoric acid supplied near the center of the backside of the wafer escapes toward the edge. Also, although a small amount of hydrofluoric acid may be mixed with deionized water near the edge, it may not have a significant effect on the removal efficiency of the oxide film on the entire backside surface.

At this time, both the front and backside surfaces of the wafer may be hydrophilic, and in order to secure the hydrophobicity of the backside of the wafer S120, the backside of the wafer may be cleaned with hydrofluoric acid (HF), and the front surface of the wafer may be rinsed at this time. The hydrofluoric acid supplied in this process can remove the oxide film (SiO₂) present on the backside of the wafer.

In addition to supplying hydrofluoric acid to remove the oxide film described above, a chemical such as hydrochloric acid (HCl), a fluorine-based gas, BOE (Buffered Oxide Etchant), or NH₄F may also be supplied.

If the wafer is rinsed after cleaning with hydrofluoric acid, various particles may be re-adsorbed and contaminated on the hydrophobic backside surface of the wafer.

Therefore, a process S130 for improving the particles on the backside surface of the wafer, that is, removing the particles, can be performed. For example, nitrogen (N₂) gas can be supplied to the backside surface of the wafer to remove the particles, and at this time, the front surface of the wafer can be rinsed.

If the above-described process is performed, the front surface of the wafer becomes hydrophilic and the backside surface of the wafer becomes hydrophobic, and most of the particles on the backside surface of the wafer can be removed. It is more efficient to supply nitrogen gas than to supply deionized water to remove the particles.

The action of nitrogen gas can remove particles, especially on the backside surface of the wafer, and also remove residual chemicals. In this process, the wafer can be rotated while supplying nitrogen gas and deionized water, and the rotation speed can be increased step by step by rotating at a low rpm.

The reason for starting with low rpm is that if the wafer is rotated quickly from the beginning, the deionized water and nitrogen gas cannot sufficiently contact the surface and can escape to the edge.

Then, by gradually increasing the rotation rpm of the wafer, the remaining liquid such as hydrofluoric acid and rinse can be removed. Here, the reason for gradually increasing the rotation rpm of the wafer is that if the rpm is rapidly increased, a pattern of liquid flow can occur, and a concentric pattern of particle can remain on the front and backside surfaces of the wafer.

Table 1 shows the surface condition of the backside surface of the wafer after cleaning when an initial rotation rpm of the wafer was changed during the supply of nitrogen gas. The number of particles below refers to the number of particles counted in one wafer. In addition, the number of particles described below all refers to the number of particles larger than 0.2 micrometers in size. As the size decreases, the number of particles increases, and as the size increases, the number of particles decreases. In this invention, 0.2 micrometers was set as the minimum level for measuring particles on the backside surface of the wafer.

TABLE 1

| Cleaning conditions (rpm) | Particle >0.2 μm |
|---|---|
| 150 | <15 |
| 300 | <100 |
| 500 | <500 |

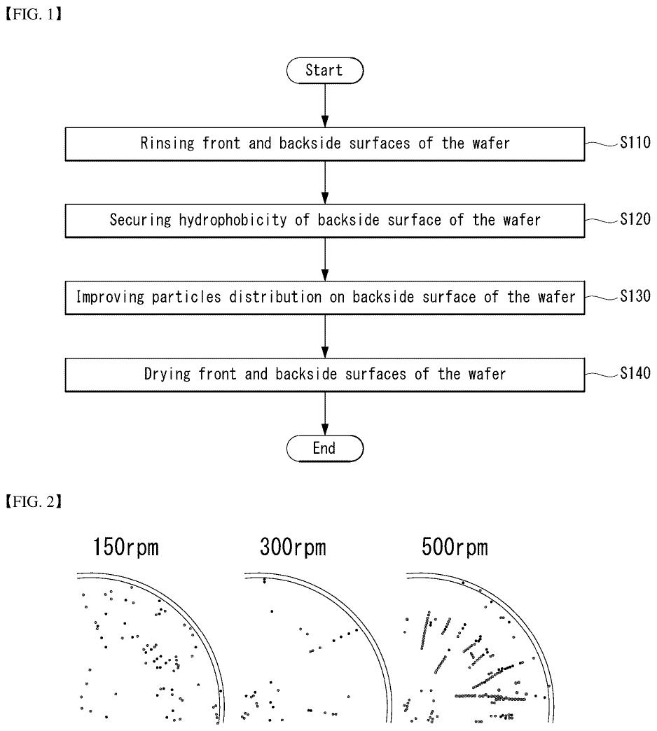

FIG. 2 shows the particle distribution on the backside surface of the wafer after cleaning according to each cleaning condition in Table 1. In Table 1 and FIG. 2, the initial supply time of nitrogen gas is 5 seconds.

From Table 1 and FIG. 2, it can be seen that when the initial rotation of the wafer is 150 rpm when the nitrogen gas is supplied, the number of particles remaining on the backside surface of the wafer after cleaning are the smallest.

Table 2 shows the surface condition of the backside surface of the wafer after cleaning when the initial supply time of the wafer is changed when the nitrogen gas is supplied.

TABLE 2

| Cleaning conditions (seconds) | Particle >0.2 μm |
|---|---|
| 2 | <15 |
| 5 | <15 |
| 10 | <20 |

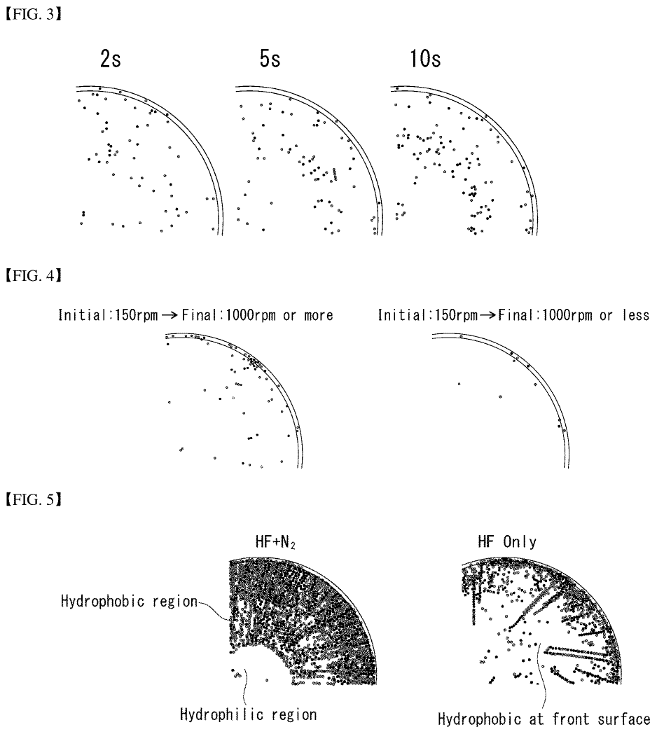

FIG. 3 shows the particle distribution on the backside surface of the wafer after cleaning according to each cleaning condition in Table 2. In Table 2 and FIG. 3, the rotation rpm of the wafer at the initial supply of nitrogen gas is 150 RPM (Revolutions per minute).

From Table 2 and FIG. 3, it can be seen that when the initial rotation time of the wafer at the supply of nitrogen gas is 2 to 5 seconds, the number of particles remaining on the backside surface of the wafer after cleaning are the smallest.

Table 3 shows the surface condition of the backside surface of the wafer after cleaning according to the final rpm of the wafer at the supply of nitrogen gas.

TABLE 3

| Cleaning conditions(final) | Particle >0.2 μm | Pattern |
|---|---|---|
| 1000 rpm or more | <100 | Yes |
| 1000 rpm or less | <10 | No |

FIG. 4 shows the particle distribution on the backside surface of the wafer after cleaning according to each cleaning condition in Table 3. In Table 3 and FIG. 4, the rotation rpm of the wafer is 150 RPM when the nitrogen gas is initially supplied.

From Table 3 and FIG. 4, it can be seen that when the rotation of the wafer is initially 150 RPM and finally 1000 RPM or less when supplying nitrogen gas, the number of particles remaining on the backside surface of the wafer after cleaning are the smallest and there is no residual pattern.

If hydrofluoric acid and nitrogen gas are supplied at the same time to simultaneously secure the hydrophobicity of the backside surface of the wafer and improve the remaining particles as described above, cleaning can be performed by supplying the liquid hydrofluoric acid and the nitrogen gas to the center of the backside surface of the wafer and then spreading out toward an edge.

If only hydrofluoric acid is supplied, the hydrofluoric acid spreads from the center of the backside surface of the wafer to the edge, and the etching of an oxide film is sufficiently performed, so that the entire backside surface of the wafer can become hydrophobic.

However, when hydrofluoric acid and nitrogen are supplied together, the center of the backside surface of the wafer may have relatively insufficient time for the etching of the oxide film by hydrofluoric acid due to the presence of nitrogen gas. Therefore, the center of the backside surface of the wafer can maintain hydrophilicity without the oxide film being sufficiently removed. At this time, the edge of the wafer is relatively less affected by the nitrogen gas spreading out, so the hydrophobicity due to the etching removal of the oxide film may proceed better than the center.

Table 4 shows the surface condition of the backside surface of the wafer after cleaning when hydrofluoric acid and nitrogen gas were used together and when only hydrofluoric acid was used for hydrophobicity of the backside surface of the wafer.

TABLE 4

| Cleaning | Surface Condition | | Particle >0.2 |
|---|---|---|---|
| Condition | Center | Edge | μm |
| HF + N₂ | hydrophilic | hydrophobic | >50,000 |
| HF only | hydrophobic | hydrophobic | <2,000 |

FIG. 5 shows the particle distribution on the backside surface of the wafer when hydrofluoric acid and nitrogen are supplied to the wafer at the same time and when only hydrofluoric acid is supplied.

From Table 4 and FIG. 5, when hydrofluoric acid and nitrogen gas are used together, in particular, the center of the backside surface of the wafer is hydrophilic because etching of the oxide film is not sufficiently performed, and many particles larger than 0.2 micrometers remain, but when only hydrofluoric acid is used, the etching removal of the oxide film is sufficiently performed at both the center and the edge of the wafer, and the number of particles larger than 0.2 micrometers is reduced to less than 2,000.

In addition, supplying nitrogen gas may be more advantageous for removing particles on the backside surface of the wafer than rinsing using deionized water.

Table 5 shows the surface conditions of the backside surface of the wafer after cleaning when only deionized water rinse is used in the S130 process described above, when the process is not performed, and when nitrogen gas is supplied.

TABLE 5

| | Surface Condition | | Particle >0.2 |
|---|---|---|---|
| Cleaning Condition | Center | Edge | μm |
| deionized water | hydrophobic | Hydrophobic | >50,000 |
| None | hydrophobic | hydrophobic | <2,000 |
| N₂ | hydrophobic | hydrophobic | <100 |

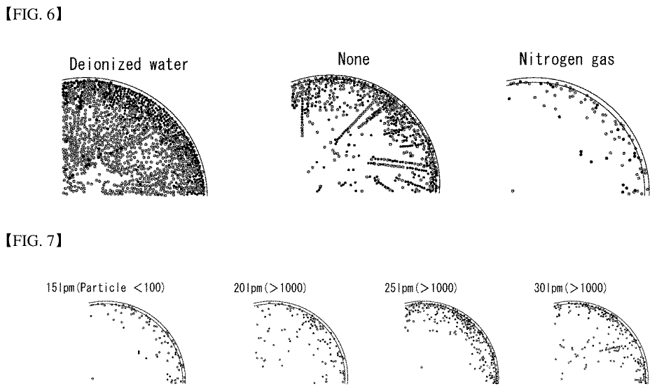

FIG. 6 shows the particle distribution on the backside surface of the wafer after cleaning in each case of Table 5.

From Table 5 and FIG. 6, it can be seen that when nitrogen gas was used, the number of particles larger than 0.2 micrometers was reduced to less than 100, but when this process was not performed, the number of particles larger than 0.2 micrometers increased to less than 2,000, and when deionized was used, the number of particles larger than 0.2 micrometers exceeded 50,000.

FIG. 7 shows the particle distribution on the back surface of the wafer after cleaning according to the supply flow rate of nitrogen gas.

As the supply flow rate of nitrogen gas increases, contamination may increase due to particles gathering near the pins supporting the wafer at the edge of the backside surface of the wafer, and in FIG. 7, supplying nitrogen gas at 15 lpm (Liter per minute) or less was able to reduce the remaining particles the most.

If the supply flow rate of nitrogen gas is less than 5 lpm, the supply effect of nitrogen gas is reduced, and particles at the edge of the backside surface of the wafer may not be sufficiently removed.

Therefore, the supply flow rate of nitrogen gas can be set to 5 to 15 lpm.

Then, the front and backside surfaces of the wafer are dried (S140), for example, the front and backside surfaces of the wafer can be dried with rotating the wafer.

According to the method for manufacturing a wafer according to the embodiments of the present invention described above, the manufactured wafer has a hydrophilic front surface and a hydrophobic backside surface, and particles on the backside surface are removed, so that the occurrence of a halo at the edge of the backside surface of the wafer can be prevented in a subsequent epitaxial layer growth process.

Although the foregoing description has been given mainly in conjunction with embodiments, these embodiments are only illustrative without limiting the disclosure. Those skilled in the art to which the present disclosure pertains can appreciate that various modifications and applications illustrated in the foregoing description may be possible without changing essential characteristics of the embodiments. Therefore, the above-described embodiments should be understood as exemplary rather than limiting in all aspects. In addition, the scope of the present disclosure should also be interpreted by the claims below rather than the above detailed description. All modifications or alterations as would be derived from the equivalent concept intended to be included within the scope of the present disclosure should also be interpreted as falling within the scope of the disclosure.

What is claimed is:

1. A method for manufacturing a wafer, comprising:
a step of rinsing front and backside surfaces of the wafer;
a step of securing hydrophobicity of the backside surface of the wafer;
a step of improving particles distribution on the backside surface of the wafer; and
a step of drying the front and backside surfaces of the wafer.

2. The method of claim 1, wherein rinse the front surface of the wafer and clean the backside surface of the wafer with hydrofluoric acid, in the step of securing hydrophobicity of the backside surface of the wafer.

3. The method of claim 1, wherein rinse the front surface of the wafer and clean the backside surface of the wafer with nitrogen gas, in the step of improving particles distribution on the backside surface of the wafer.

4. The method of claim 1, wherein rotate the wafer in the step of drying the front and backside surfaces of the wafer.

5. The method of claim 1, wherein the rotation speed of the wafer is gradually increased from low rpm to high rpm, in the step of improving particles distribution on the backside surface of the wafer.

6. The method of claim 1, wherein the nitrogen gas is supplied at a flow rate of 5 to 15 lpm, in the step of improving particles distribution on the backside surface of the wafer.

7. The method of claim 1, wherein the rotation speed of the wafer is started at 150 RPM or less, in the step of improving particles distribution on the backside surface of the wafer.

8. The method of claim 7, wherein the wafer is rotated at 150 RPM or less for 2 to 5 seconds, in the step of improving particles distribution on the backside surface of the wafer.

9. The method of claim 1, the rotation speed of the wafer is finally set to 1000 RPM or less, in the step of improving particles distribution on the backside surface of the wafer.
